(19) United States
(12) Patent Application Publication
(10) Pub. No.: US 2012/0049906 A1
(43) Pub. Date: Mar. 1, 2012

(54) Power On/Reset Circuit and Method of Controlling On/Reset Status of Digital Circuit thereof

(76) Inventor: Wei-Jie Lee, Hsinchu County (TW)

(21) Appl. No.: 13/047,797

(22) Filed: Mar. 15, 2011

(30) Foreign Application Priority Data
Aug. 31, 2010 (TW) 099129324

(51) Int. Cl. H03L 7/00

(52) U.S. Cl. 327/143

(57) ABSTRACT

A power on/reset circuit includes a voltage following module, an inverse amplifying module, and at least one first transistor connected in series in a stack. The voltage following module generates a first analog signal, whose voltage level follows a voltage level of a first DC voltage source. The inverse amplifying module logically reverses a voltage level of the first analog signal so as to generate a second analog signal. The at least one first transistor adjusts the second analog signal, so that a voltage level of a power on/reset signal controlled by the second analog signal is qualified to precisely trigger a rear digital circuit.

### BACKGROUND OF THE INVENTION

1. Field of the Invention

The present invention relates to a power on/reset circuit and a method of controlling an on/reset status of a digital circuit thereof, and more particularly, to a power on/reset circuit including at least one transistor connected-in-series in a stack and a method of controlling an on/reset status of a digital circuit.

2. Description of the Prior Art

A conventional integrated circuit is configured to acquire a system-on-a-chip (SOC) type or a mixed mode type for integrating more functions, such as integrating digital circuits and analog circuits. The integrated digital circuits provides functions including controlling, logic operations, data storage, and setting an initial condition of the integrated circuit, where the setting of the initial condition requires a power on/reset signal.

Please refer to FIG. 1 and FIG. 2, which illustrates two conventional integrated circuits. FIG. 1 illustrates an integrated circuit 100, which includes a power on/reset circuit 110, a regulator 120, a power on/reset impulse generator 130, and a digital circuit 140. The power on/reset circuit 110 and the regulator 120 are supplied with power from a DC voltage source VDD. The power on/reset circuit 110 is utilized for generating a power on/reset signal, so as to determine a timing of activating or resetting the digital circuit 140. The Power on/reset 130 generates a reset impulse according to the power on/reset signal from the power on/reset circuit 110 and the power from the regulator 120, so as to render the digital circuit 140 to be activated or reset according to an activated time of the power on/reset signal, such as a duty cycle of the power on/reset signal. Similarly, FIG. 2 illustrates an integrated circuit 200, which includes the power on/reset circuit 110, the regulator 120, a power on/reset impulse generator 230, and the digital circuit 140. The power on/reset impulse generator 230 also generates the reset impulse according to the power from the regulator 120 and the power on/reset signal from the power on/reset circuit 110, so as to determine a timing of activating or resetting the digital circuit 140 on time. A conventional integrated circuit, such as the integrated circuits 100 and 200, is utilized for resetting the digital circuit in the manners shown in FIG. 1 or FIG. 2.

Under an ideal condition, the voltage source VDD for providing the integrated circuits 100 and 200 with power is merely activated once, then continues its operations. However, under practical uses or tests, ideal conditions may occur so that the power is switched on or off repeatedly. For example, first, a voltage source for providing power to the digital circuit is activated so as to acquire a voltage level from 0 volts to 3 volts; second, the voltage source is switched off so that the voltage level of the voltage source drops from 3 volts to 0.9 volts; and at third, the voltage source is activated again so that the voltage level of said voltage source is raised again from 0.9 volts to 3 volts, and it indicates an non-ideal condition of the voltage source.

Please refer to FIG. 3, which illustrates a conventional power on/reset circuit 250 for generating the abovementioned power on/reset signal. As shown in FIG. 3, the power on/reset 250 includes a voltage following module 310, a P-type MOSFET QS1, an N-type MOSFET QS2, and an inverter INV, where the voltage following module 310 is provided with power by a DC voltage source VCC. The voltage following module 310 generates a voltage V1, whose voltage level follows a voltage level of the DC voltage source VCC. The P-type MOSFET QS1 and the N-type MOSFET QS2 cooperates as an inverter for the voltage V1, so as to render a generated voltage V2 acquiring a logically-reversed voltage level against the voltage V1. At last, the voltage V2 is transformed into the power on/reset signal shown in FIG. 3 with the aid of the inverter INV. For example, first, in the power on/reset circuit 250, the voltage level of the voltage source VCC is raised from 0 volts to 3 volts, and the voltage level of the voltage V1 follows the voltage source V1 to raise up; before the voltage level of the voltage V1 is raised enough to trigger the inverter consist of the transistors QS1 and QS2, the voltage level of the voltage V2 equals to the voltage level of the voltage source VCC, so that the inverter INV continues to output a logic-low voltage level acquiring 0 volts, i.e., the generated power on/reset signal is logically low so as to reset the rear digital circuit; second, while the voltage V1 is raised up enough to trigger the inverter consist of the transistors QS1 and QS2, the voltage V2 is transit to a logically-low voltage level, so as to render the inverter INV outputs a voltage acquiring 3 volts for ceasing resetting the digital circuit; however, at third, while the voltage level of the voltage source VCC appears to be dropped from 3 volts to 0.9 volts and be raised up 3 volts again, as the abovementioned condition goes, the power on/reset 250 will not reset the rear digital circuit 250 again; moreover, the 0.9-volt voltage level of the voltage source VCC has been lower than a normal-operational voltage level so that recorded data in the digital circuit will enter an unknown status, and as a result, the digital circuit will fail its normal operations. As a summary, failure of the digital circuit is resulted from the condition that the voltage V1, which follows the voltage source VCC by its voltage level, is not high enough to trigger the inverter consist of the transistors QS1 and QS2 to initiate a next transition.

### SUMMARY OF THE INVENTION

The claimed invention discloses a power on/reset circuit, which comprises a voltage following circuit and a reverse amplifying module. The voltage following circuit is coupled to a first DC voltage source. The voltage following module is used for generating a first analog signal, a voltage level of which follows a voltage level of the first DC voltage source. The reverse amplifying module is used for receiving the first analog signal and for generating a second analog signal, which acquires a logically-reversed voltage level against the first analog signal. The power on/reset circuit controls an on/reset status of a digital circuit according to the second analog signal. The reverse amplifying module adjusts the second analog signal with the aid of stacked transistors.

The claimed invention also discloses a method of controlling an on/reset status of a digital circuit. The method comprises rendering a voltage level of a first analog signal to follow a voltage level of a first DC voltage source; logically reversing the voltage level of the first analog signal, so as to generate a second analog signal; adjusting an initial condition of logically reversing the voltage level of the first analog signal, and adjusting the second analog signal by using stacked transistors; and controlling an on/reset signal according to the second analog signal, and controlling an on/reset status of a digital circuit according to the on/reset signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-2 illustrate two conventional integrated circuits.

FIG. 3 illustrates a conventional power on/reset circuit.

FIG. 4 illustrates a power on/reset circuit according to an embodiment of the present invention.

FIG. 5 illustrates a voltage transfer characteristic of the reverse amplifying module shown in FIG. 8 for right-shifting the voltage transfer characteristic curve with the aid of at least one transistors connected in series in a stack.

FIGS. 6-7 illustrate waveforms of outputted power on/reset signals while respectively providing a non-ideal voltage source to the power on/reset circuits in FIG. 3 and FIG. 4.

FIGS. 8-13 illustrate a plurality of embodiments of the reverse amplifying modules shown in FIG. 4 according to embodiments of the present invention.

FIG. 14 illustrates a schematic diagram of an operational method of the power on/reset circuit shown in FIGS. 4-13.

### DETAILED DESCRIPTION

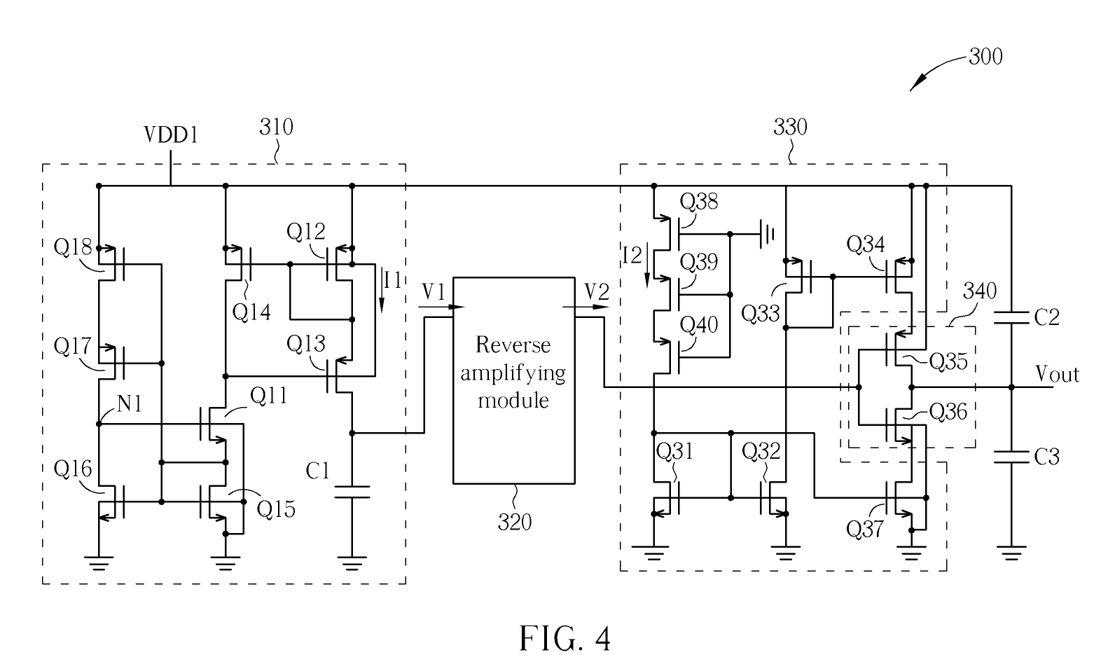

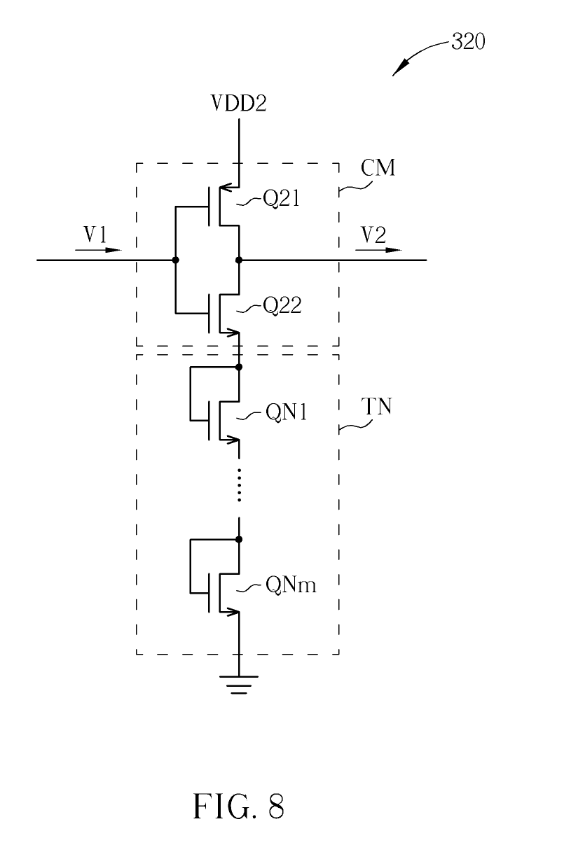

Please refer to FIG. 4, which illustrates the power on/reset circuit 300 of the present invention. As shown in FIG. 4, the power on/reset circuit 300 includes a voltage following module 310, a reverse amplifying module 320, a voltage supplier 330, and a reverse logic module 340. Please refer to FIG. 8 as well. FIG. 8 illustrates details of the reverse amplifying module 320 shown in FIG. 4 according to an embodiment of the present invention. As shown in FIG. 8, the reverse amplifying module 320 includes an inverter CM and a transistor set TN.

The voltage following module 310 includes P-type MOSFETs Q12, Q13, Q14, Q17, and Q18, N-type MOSFETs Q11, Q15, and Q16, and a capacitor C1, and is coupled to a DC voltage source VDD1 so as to form the equivalent current source I1 shown in FIG. 4. The P-type MOSFET Q12 has a source coupled to the DC voltage source VDD1. The P-type MOSFET Q13 has a source coupled to both drain and gate of the P-type MOSFET Q12, and has a base coupled to a base of the P-type MOSFET Q12. The P-type MOSFET Q14 has a source coupled to the source of the P-type MOSFET Q12, has a gate coupled to the gate of the P-type MOSFET Q12, and has a drain coupled to a gate of the P-type MOSFET Q13. The N-type MOSFET Q11 has a drain coupled to both a drain of the P-type MOSFET Q14 and the gate of the P-type MOSFET Q13. The N-type MOSFET Q15 has a drain coupled to both the source of the N-type MOSFET Q11 and a gate of the N-type MOSFET Q15. The N-type MOSFET Q16 has a source coupled to ground, has a gate coupled to the gate of the N-type MOSFET Q15, and has a drain coupled to the gate of the N-type MOSFET Q11. N-type MOSFET Q17 has a drain coupled to the drain of the N-type MOSFET Q16, and has a gate coupled to the gate of the N-type MOSFET Q15. The P-type MOSFET Q18 has a drain coupled to a source of the P-type MOSFET Q17, has a gate coupled to the gate of the P-type MOSFET Q17, and has a source coupled to the source of the P-type MOSFET Q12. In the voltage following module 310, the voltage level of the analog signal V1 follows the voltage level of the DC voltage source VDD1, i.e., similar to the condition that the voltage level of the analog signal V1 follows the voltage level of the DC voltage source VCC as mentioned before.

The transistor set TN includes at least one N-type MOSFETs QN1, . . . , QNN connected in series as a stack. The transistor QN1 is coupled to an inverter CM, and a source of the transistor SNMP is coupled to ground. The inverter CM includes a P-type MOSFET Q21 and an N-type MOSFET Q22. The N-type MOSFET Q22 has a gate coupled to an output terminal of the voltage following module 310 for receiving an analog signal V1. The P-type MOSFET Q21 has a gate coupled to a gate of the N-type MOSFET Q22, has a source coupled to a DC voltage source VDD2, and has a drain coupled to a drain of the N-type MOSFET Q22 for outputting an analog signal V2, which is logically-inverse to the analog signal V1 by its voltage level and is utilized for controlling a power on/reset status of a rear digital circuit. The transistor QN1 has a drain coupled to the source of the N-type MOSFET Q22.

The current supplier 330 includes N-type MOSFETs Q31, Q32, and Q37, and P-type MOSFETs Q33 and Q34. The N-type MOSFET Q31 has a drain coupled to the DC voltage source VDD1 and a gate of the N-type MOSFET Q31 through an equivalent current source I2 generated by the current supplier 330. The N-type MOSFET Q32 has a gate coupled to the gate of the N-type MOSFET Q31. The N-type MOSFET Q37 has a gate coupled to the gate of the N-type MOSFET Q32. The P-type MOSFET Q33 has a gate and a drain both coupled to a drain of the N-type MOSFET Q32, and has a source coupled to the DC voltage source VDD1. The P-type MOSFET Q34 has a gate coupled to the gate of the P-type MOSFET Q33, and has as source coupled to the DC voltage source VDD1. The current supplier 330 further includes three P-type MOSFETs Q38, Q39, and Q40, gates of which are mutually coupled and coupled to ground. The P-type MOSFET Q38 has a source coupled to the DC voltage source VDD1, and has a drain coupled to a source of the P-type MOSFET Q39. The P-type MOSFET has a drain coupled to a source of the P-type MOSFET Q40. The P-type MOSFET Q40 has a drain coupled to the drain of the N-type MOSFET Q31.

The reverse logic module 340 includes a P-type MOSFET Q35 and an N-type MOSFET Q36. The P-type MOSFET Q35 has a gate coupled to the inverter CM, and has a source coupled to the drain of the P-type MOSFET Q34. The N-type MOSFET Q36 has a gate coupled to the gate of the P-type MOSFET Q35, has a drain coupled to a drain of the P-type MOSFET Q35, and has a source coupled to the drain of the N-type MOSFET Q37. The P-type MOSFET Q35 has a base coupled to the DC voltage source VDD1. The N-type MOSFET Q36 has a base coupled to a base of the N-type MOSFET Q37. An equivalent capacitor C2 is formed along with the output voltage Vout, and an equivalent capacitor C3 is formed by the MOSFETs Q36 and Q37. The reverse logic module 340 retrieves a required operation current from MOSFETs Q32, Q33, Q34, and Q37 of the current supplier 330. The current supplier 330 is also utilized for controlling a magnitude of the retrieved operation current below a critical current magnitude, so as to generate a power on/reset signal Vout located at between the capacitors C2 and C3 as shown in FIG. 4. A voltage level of the power on/reset signal Vout is logically-inverse to the voltage level of the second analog signal V2, and is directly used for controlling a power on/reset status of the abovementioned digital circuit. In other words, the power on/reset status of the digital circuit may be indirectly controlled with the aid of the second analog signal V2.

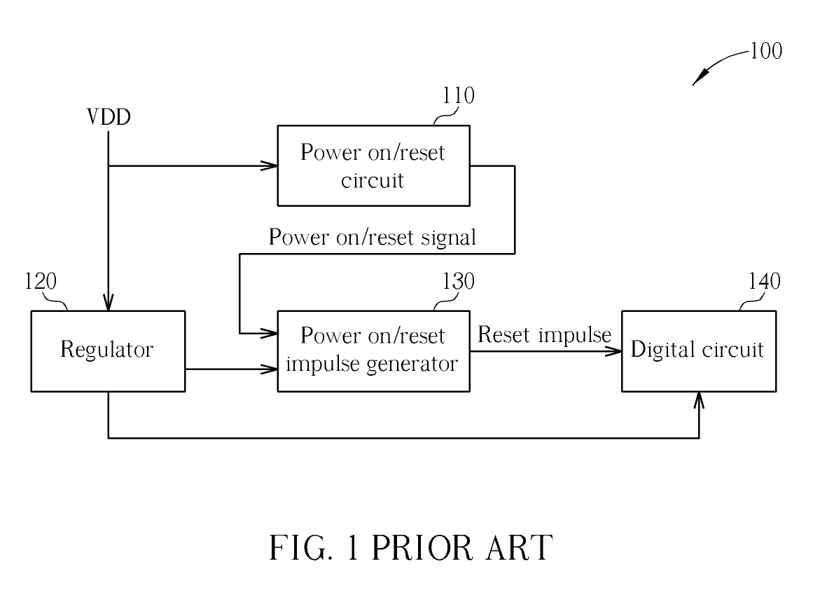

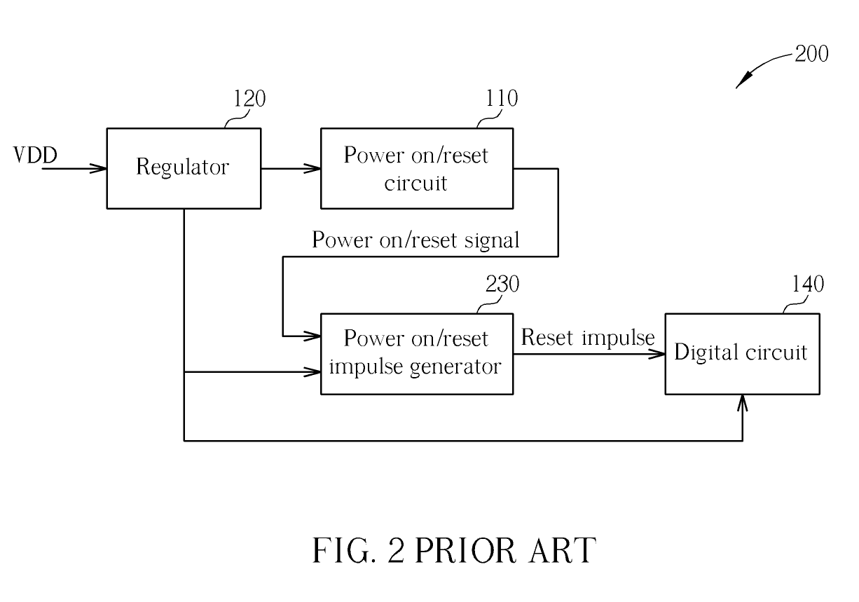

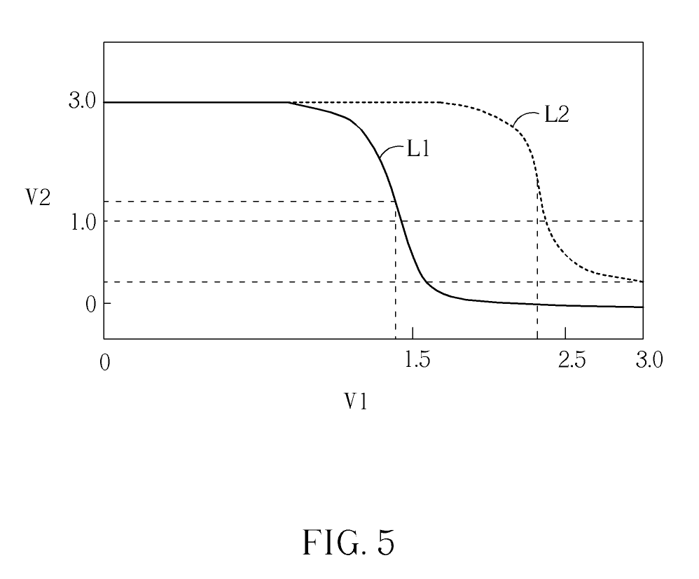

In the reverse amplifying module 320 shown in FIG. 4 and FIG. 8, a voltage level at a node N1, which is located at the gate of the N-type MOSFET Q11, is raised up with the aid of the DC voltage source VDD1. While the voltage level at the node N1 is raised up enough to turn on the MOSFET Q11, the capacitor C1 is charged by the current source I1 through the P-type MOSFETs Q12 and Q13. By charging the capacitor C1, the analog signal V1 is generated at the drain of the MOSFET Q13 and is provided to the reverse amplifying module 320. The voltage level of the analog signal V1 directly affects the voltage level of the analog signal V2 outputted by the reverse amplifying module 320, and thereby affects the voltage level of the power on/reset signal Vout provided to the rear digital circuit. Please refer to FIG. 5, which illustrates voltage transfer characteristic curves L1 and L2 of the reverse amplifying module 320 for indicating voltage levels of the DC voltage source VDD1 and the power on/reset signal Vout. As shown in FIG. 1, with the aid of the transistors connected in series in a stack of the transistor set TN, the voltage transfer characteristic curve is transit from L1 to L2 so that the analog signal V2 is capable of triggering a transition, instead of being unable to triggering the transition in the prior arts; that is, the reverse amplifying module 320 will issue the power on/reset signal Vout to the digital power on/reset impulse generator 230 shown in FIGS. 1-2, by passing the reverse logic module 340, so as to generate a reset pulse to reset the digital circuit 140 shown in FIGS. 1-2.

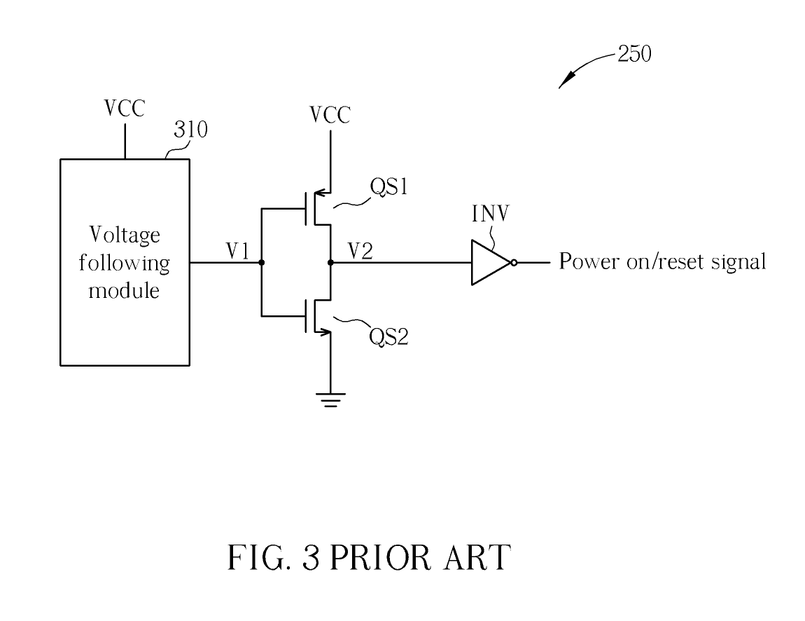

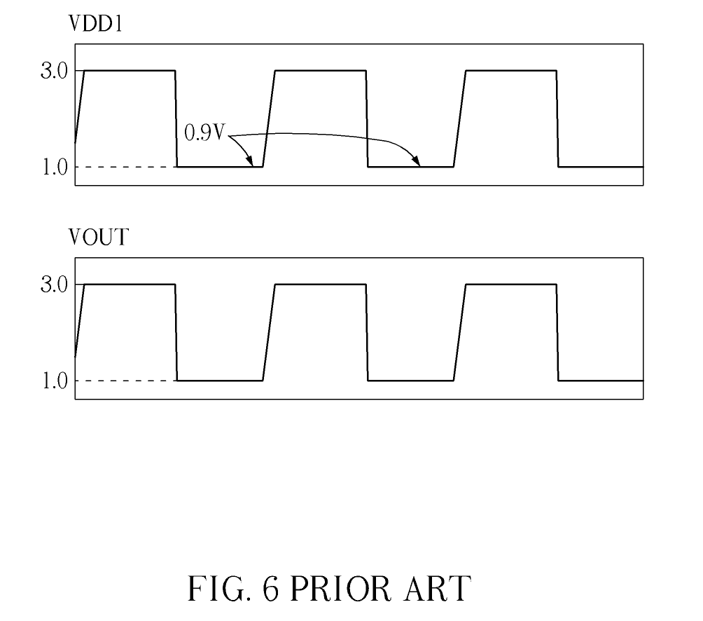

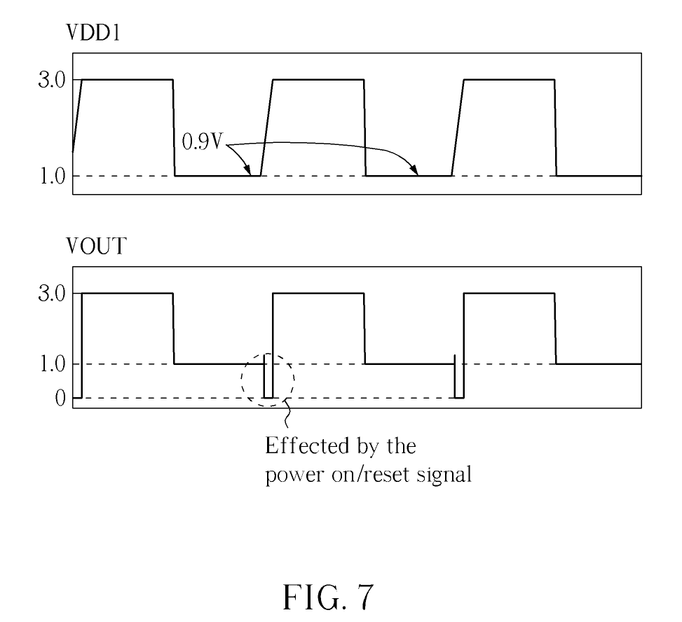

Please refer to FIG. 6 and FIG. 7, both of which illustrates the voltage transfer characteristic curve shown in FIG. 5, under a condition that the DC voltage source VDD1 is repeatedly switched on and off, to indicate the voltage level of the power on/reset Vout while the non-ideal DC voltage source VDD1 is used for providing power to the power on/reset circuit 250 shown in FIG. 3 and the power on/reset circuit 300 shown in FIG. 8 as a comparison. As shown in FIG. 6, the voltage level of the power on/reset signal Vout is dropped down from 3 volts to 0.9 volts, by following the non-ideal DC voltage source VDD1 from 3 volts to 0.9 volts, therefore, the abovementioned defect that the power on/reset signal is unable to trigger the rear digital circuit will come out. However, as can be observed in FIG. 7, under the same condition as FIG. 6, the voltage level of the power on/reset signal Vout is instantly dropped down to 0 volts with the aid of both the inverter CM and the transistor set TN, and is raised up from 0 volts to 3 volts. Therefore, the voltage level of the power on/reset signal Vout is sufficient to trigger the rear digital circuit, and is configured to the prior-arts defect of unable to trigger the rear digital circuit.

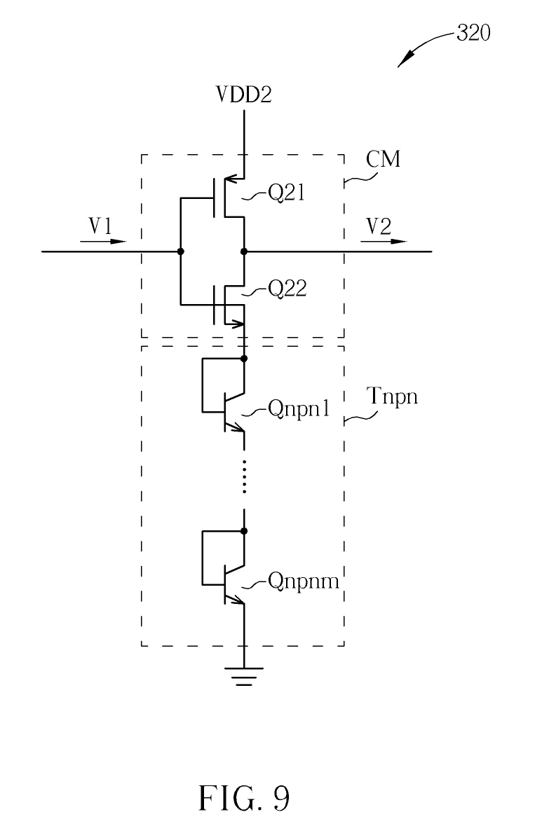

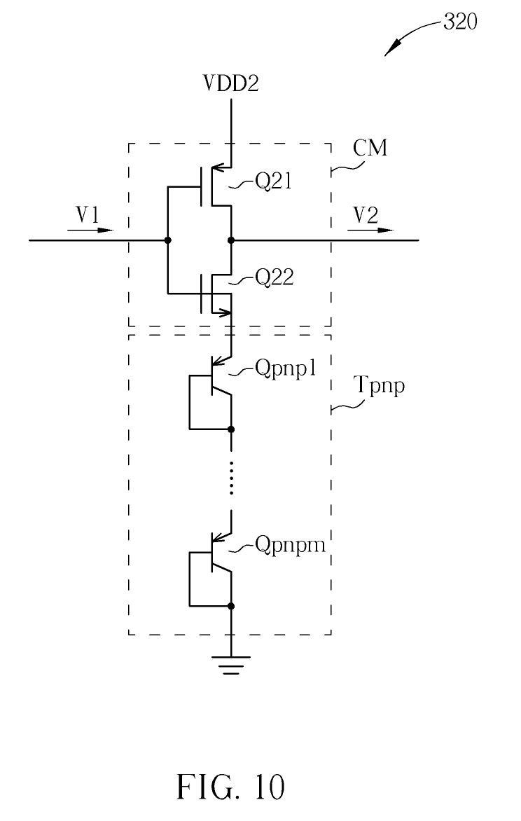

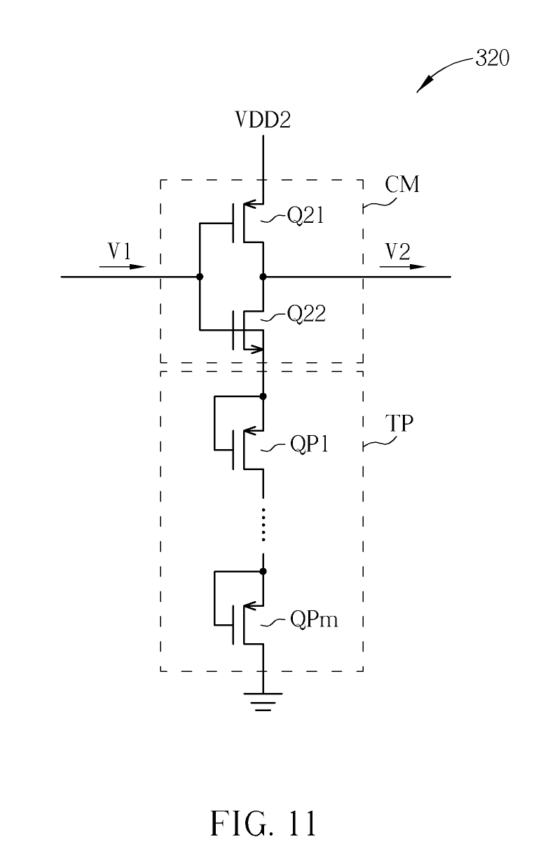

In other embodiments of the present invention, the transistor set TN shown in FIG. 8 may be replaced by the transistor sets Tnpn shown in FIG. 9, Tpnp shown in FIG. 10, and TP shown in FIG. 11, so as to fulfill the same purpose with the transistor set TN shown in FIG. 8. The transistor set Tnpn includes at least one npn-type BJTs Qnpn1, . . . , and Qnpnm connected in series in a stack. The transistor set Tpnp includes at least one pnp-type BJTs Qpnp1, . . . , and Qpnpm connected in series in a stack. The transistor set TP includes at least one P-type MOSFETs QP1, . . . , and QPm connected in series in a stack.

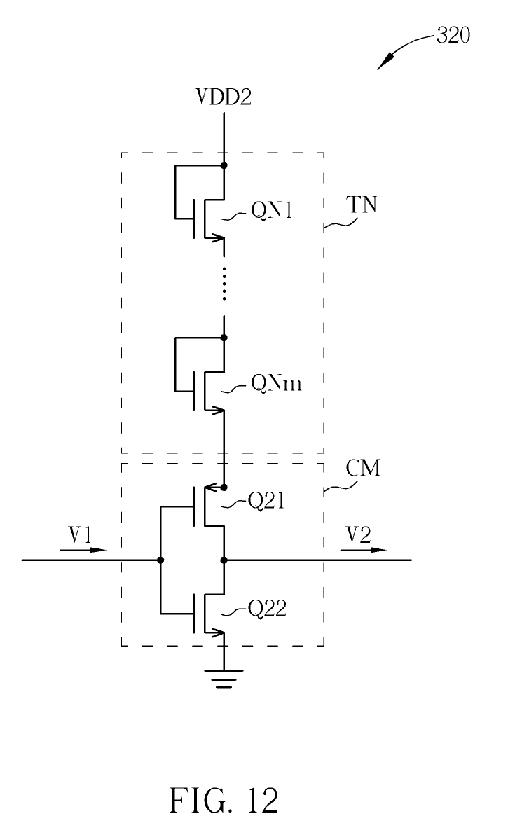

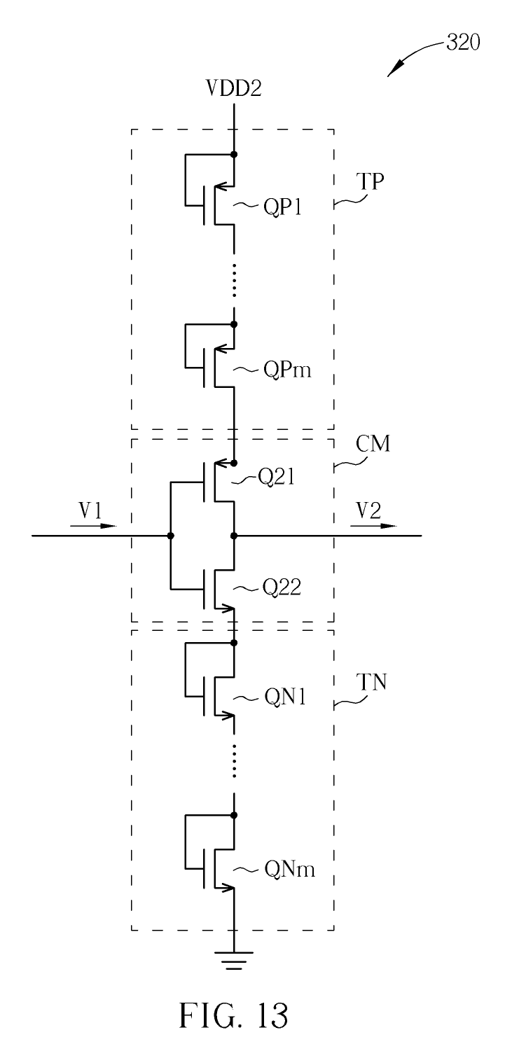

Besides, in certain embodiments of the present invention, the disposition of the transistor sets TN, TP, Tnpn, and Tpnp are not restricted to be coupled to the N-type MOSFET Q22. As shown in FIG. 12, the transistor set TN is directly coupled to the P-type MOSFET Q21, the drain of the MOSFET QN1 is coupled to the DC voltage source VDD1, and the source of the MOSFET QN1 is coupled to the source of the P-type MOSFET Q21. While the transistor set TN shown in FIG. 12 is replaced by the transistor sets TP, Tnpn, and Tpnp, the dispositions are similar so that repeated dispositions are not repeatedly described herein. Moreover, as shown in FIG. 13, the P-type MOSFET Q21 and the N-type MOSFET Q22 of the inverter CM may also be respectively coupled to the transistor sets TP and TN. In other embodiments of the present invention, the transistor sets TN and TP may also be replaced by the transistor sets Tnpn and Tpnp, therefore, embodiments formed by replacing the transistor sets in FIGS. 12-13 by the transistor sets shown in FIGS. 8-11 are still configured to be embodiments of the present invention.

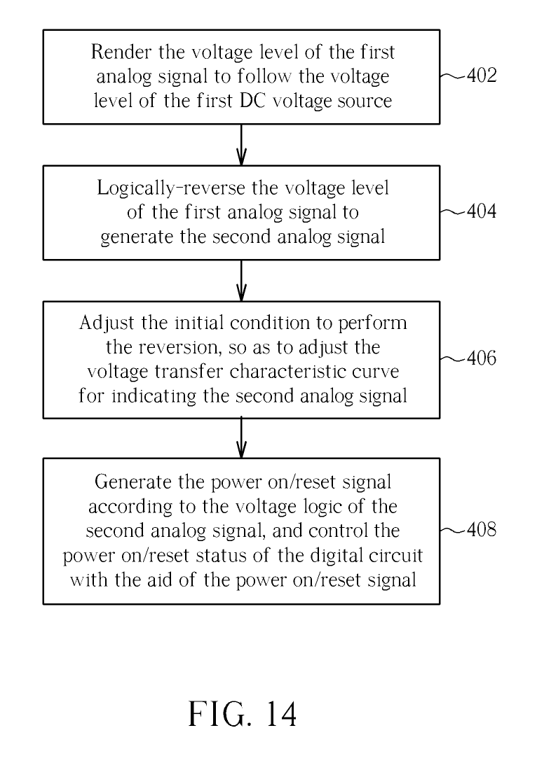

Please refer to FIG. 14, which schematically illustrates an operation method of the power on/reset circuit shown in FIGS. 4-13. As shown in FIG. 14, the method includes steps as follows:

Step 402: Render the voltage level of the first analog signal to follow the voltage level of the first DC voltage source.

Step 404: Logically-reverse the voltage level of the first analog signal to generate the second analog signal.

Step 406: Adjust the initial condition to perform the reversion, so as to adjust the voltage transfer characteristic curve for indicating the second analog signal.

Step 408: Generate the power on/reset signal according to the voltage logic of the second analog signal, and control the power on/reset status of the digital circuit with the aid of the power on/reset signal.

Those skilled in the art will readily observe that numerous modifications and alterations of the device and method may be made while retaining the teachings of the invention.

What is claimed is:

1. A power on/reset circuit, comprising:
a voltage following circuit, coupled to a first DC voltage source, the voltage following module being used for generating a first analog signal, a voltage level of which follows a voltage level of the first DC voltage source; and
a reverse amplifying module, used for receiving the first analog signal and for generating a second analog signal, which acquires a logically-reversed voltage level against the first analog signal;
wherein the power on/reset circuit controls a on/reset status of a digital circuit according to the second analog signal; and
wherein the reverse amplifying module adjusts the second analog signal with the aid of stacked transistors.

2. The power on/reset circuit of claim 1, wherein the reverse amplifying module comprises:
a first N-type MOSFET, having a gate coupled to an output terminal of the voltage following module for receiving the first analog signal; and
a first P-type MOSFET, having a gate coupled to the gate of the first N-type MOSFET, having a source coupled to a second DC voltage source, and having a drain coupled to a drain of the first N-type MOSFET for outputting the second analog signal;
wherein the power on/reset circuit further comprises at least one first transistor, one of which is coupled to a source of the first N-type MOSFET.

3. The power on/reset circuit of claim 2, wherein a voltage level of the second DC voltage source is higher than the voltage level of the first DC voltage source.

4. The power on/reset circuit of claim 2, further comprising:
at least one second transistor connected in series as a stack, one of the at least one second transistor is coupled to the second DC voltage source, and another one of the at least one second transistor is coupled to the source of the first P-type MOSFET.

5. The power on/reset circuit of claim 4, wherein the at least one first transistor are N-type MOSFETs, and the at least one second transistor are P-type MOSFETs.

6. The power on/reset circuit of claim 4, wherein the at least one transistor are P-type MOSFETs, and the at least one second transistor are N-type MOSFETs.

7. The power on/reset circuit of claim 4, wherein the at least one transistor are npn-type BJTs, and the at least one second transistor are pnp-type BJTs.

8. The power on/reset circuit of claim 4, wherein the at least one transistor are pnp-type BJTs, and the at least one second transistor are npn-type BJTs.

9. The power on/reset circuit of claim 1, wherein the reverse amplifying module comprises:
a first N-type MOSFET, having a gate coupled to an output terminal of the voltage following module for receiving the first analog signal; and
a first P-type MOSFET, having a gate coupled to the gate of the first N-type MOSFET, having a source coupled to a second DC voltage source, and having a drain coupled to a drain of the first N-type MOSFET, for outputting the second analog signal;
wherein power on/reset circuit further comprises at least one first transistor, one of which is coupled to the source of the first P-type MOSFET.

10. The power on/reset circuit of claim 9, wherein a voltage level of the second DC voltage source is higher than the voltage level of the first DC voltage source.

11. The power on/reset circuit of claim 9, further comprising:
at least one second transistor connected in series as a stack, one of the at least one second transistor is coupled to the source of the first N-type MOSFET.

12. The power on/reset circuit of claim 11, wherein at the least one first transistor are N-type MOSFETs, and the at least one second transistor are P-type MOSFETs.

13. The power on/reset circuit of claim 11, wherein at the least one first transistor are P-type MOSFETs, and the at least one second transistor are N-type MOSFETs.

14. The power on/reset circuit of claim 11, wherein at the least one first transistor are npn-type BJTs, and the at least one second transistor are pnp-type BJTs.

15. The power on/reset circuit of claim 11, wherein at the least one first transistor are pnp-type BJTs, and the at least one second transistor are npn-type BJTs.

16. The power on/reset circuit of claim 1, where the voltage following module comprises:
a first P-type MOSFET, having a source coupled to the first DC voltage source;
a second P-type MOSFET, having a source coupled to both drain and gate of the first P-type MOSFET, and having a base coupled to a base of the first P-type MOSFET;
a third P-type MOSFET, having a source coupled to the source of the first P-type MOSFET, having a gate coupled to the gate of the first P-type MOSFET, and having a drain coupled to the gate of the second P-type MOSFET;
a first N-type MOSFET, having a drain coupled to the drain of the third P-type MOSFET and the gate of the second P-type MOSFET;
a second N-type MOSFET, having a drain coupled to a source of the N-type MOSFET and a gate of the second N-type MOSFET, and having a source coupled to ground;
a third N-type MOSFET, having a source coupled to ground, having a gate coupled to the gate of the second N-type MOSFET, and having a drain coupled to the gate of the first N-type MOSFET;
a fourth P-type MOSFET, having a drain coupled to the drain of the third MOSFET, and having a gate coupled to the gate of the second N-type MOSFET; and
a fifth P-type MOSFET, having a drain coupled to a source of the fourth P-type MOSFET, having a gate coupled to the gate of the fourth P-type MOSFET, and having a source coupled to the source of the first P-type MOSFET.

17. The power on/reset circuit of claim 1, further comprising:
a current supplier, coupled to the first DC voltage source for generating a current; and
a reverse logic module, coupled to the reverse amplifying module for receiving the second analog signal, and coupled to the current supplier so as to be driven by the current;
wherein the current supplier is used for keeping a magnitude of the current below a critical current magnitude, and the reverse logic module logically reverses the voltage level of the second analog signal so as to generate an on/reset signal, so as to render the power on/reset circuit to control an on/reset status of the digital circuit according to the on/reset signal.

18. The power on/reset circuit of claim 17,
wherein the current supplier comprises:
a second N-type MOSFET, having a drain coupled to the first DC voltage source and a gate of the second N-type MOSFET;
a third N-type MOSFET, having a gate coupled to the gate of the second N-type MOSFET;
a fourth N-type MOSFET, having a gate coupled to the gate of the third N-type MOSFET;
a fifth P-type MOSFET, having a gate and a drain, both of which coupled to a drain of the third N-type MOSFET, and having a source coupled to the first DC voltage source; and
a sixth P-type MOSFET, having a gate coupled to the gate of the fifth P-type MOSFET, and having a source coupled to the first DC voltage source;
wherein the reverse logic module comprises:
a seventh P-type MOSFET, having a gate coupled to the reverse amplifying module, and having a source coupled to the drain of the sixth P-type MOSFET; and
a fifth N-type MOSFET, having a gate coupled to the gate of the seventh P-type MOSFET, having a drain coupled to a drain of the seventh P-type MOSFET, and having a source coupled to the drain of the fourth N-type MOSFET;
wherein the seventh P-type MOSFET has a base coupled to the first DC voltage source, and the fifth N-type MOSFET has a base coupled to a base of the N-type MOSFET.

19. The method of controlling an on/reset status of a digital circuit, comprising:
rendering a voltage level of a first analog signal to follow a voltage level of a first DC voltage source;
logically reversing the voltage level of the first analog signal, so as to generate a second analog signal;
adjusting an initial condition of logically reversing the voltage level of the first analog signal, and adjusting the second analog signal by using stacked transistors; and
controlling an on/reset signal according to the second analog signal, and controlling an on/reset status of a digital circuit according to the on/reset signal.

20. The method of claim 19, further comprising:
logically reversing a voltage level of the second analog signal so as to generate the on/reset signal, for controlling the on/reset status of the digital circuit according to the on/reset signal.
